(19) United States
(12) Patent Application Publication
(10) Pub. No.: US 2003/0219547 A1
(43) Pub. Date: Nov. 27, 2003

(54) CVD treatment device

(76) Inventors: Gregor Arnold, Bodenheim (DE); Stephen Behle, Hahnheim (DE); Andreas Luttringhaus-Henkel, Darmstadt (DE); Matthias Bicker, Mainz (DE)

Correspondence Address: M. Robert Kestenbaum, 11011 Bermuda Dunes NE, Albuquerque, NM, 87111, US

(21) Appl. No.: 10/446,189

(22) Filed: May 26, 2003

(30) Foreign Application Priority Data
May 24, 2002 (DE) 102 23 288.1
Jun. 27, 2002 (DE) 102 28 898.4-45

(51) Int. Cl. C23C 16/00

(52) U.S. Cl. 427/569; 427/255.28; 118/718; 118/730

(57) ABSTRACT

To make it easier to move workpieces into and out of reactors in order for them to be treated by CVD therein, the invention provides a device for the CVD treatment of workpieces which comprises a conveyor and at least one reactor secured to the conveyor, the device having at least one mechanical control cam and the reactor having an opening and closing device that is actuated by the at least one control cam.

### CROSS-REFERENCE TO RELATED APPLICATIONS

Not applicable.

### STATEMENT REGARDING FEDERALLY SPONSORED RESEARCH OR DEVELOPMENT

Not applicable.

### BACKGROUND OF THE INVENTION

The invention relates to a CVD treatment device, in particular to a CVD treatment device with CVD reactors.

### TECHNICAL FIELD

Hollow plastic containers, such as for example plastic bottles, generally have a barrier action to gases which is insufficient for the intended purpose. For example, gases such as carbon dioxide can diffuse out of the container or into the container. This effect is generally undesirable. This effect leads, inter alia, to a reduction in the shelf life of beverages stored in these containers.

To eliminate these drawbacks of plastic containers while retaining their advantages, which are otherwise numerous, such as a low weight and stability with respect to mechanical impacts, techniques have been developed for applying barrier layers or diffusion resistant layers.

A particularly effective and inexpensive technique used to apply such layers is chemical vapor deposition (CVD). In CVD processes, a layer is deposited by means of a reactive chemical gas mixture which surrounds the surface which is to be coated.

A virtually unlimited range of possible layers can be produced in this way from mixtures of various gases. Inter alia oxide layers, such as for example SiO₂ layers, have proven to be suitable diffusion barriers.

A chemically reactive gas mixture can be generated thermally or by ionization of the process gases by introduction of energy in order to carry out the CVD coating. Since plastics are generally insufficiently thermally stable or have low softening points, CVD coating under the action of heat is unsuitable for coating plastic surfaces. However, in this context, the option of plasma-enhanced CVD (PECVD) coating is recommended. Since in this case too the plasma heats the surface which is to be coated, plasma impulse induced CVD coating (PICVD) is particularly suitable.

To allow a process of this type to be used on an industrial scale, the process times require a large number of chambers in which a coating operation is carried out simultaneously or offset in terms of time. Since PICVD coatings are carried out under low-pressure conditions, the problem arises of how to introduce the workpieces which are to be coated, such as for example hollow plastic bodies, into the coating regions and evacuate them. Furthermore, in the case of hollow bodies, it is often useful to coat either only the inner wall or outer wall or to apply different coatings to the outer wall and the inner wall, with the result that the interior space of the hollow body and the area which surrounds the hollow body have to be filled with different process gases.

### SUMMARY OF THE INVENTION

Therefore, the object of the present invention is to make it easier to move workpieces into and out of reactors in order for them to be treated by CVD. This object is achieved in a very surprisingly simple way by a device for the CVD treatment of workpieces comprising a conveyor and at least one reactor secured to the top conveyor, wherein the device has at least one mechanical control cam and the reactor has an opening and closing device that is actuated by the at least one control cam. The object of the invention is also achieved by a process for the CVD treatment of workpieces in a reactor that is secured to a conveyor, comprising the steps of:

inserting the workpiece into the reactor,

evacuating at least a region of the reactor chamber,

introducing a process gas,

generating a plasma, and

removing the workpiece.

The process also comprises the step of opening and/or closing the reactor by a deviced secured to the reactor by movement past a mechanical control cam.

Accordingly, a device according to the invention comprises a conveyor and at least one reactor which is secured to the conveyor and in which the CVD treatment is performed, the device having at least one mechanical control cam and the reactor having an opening and closing device that is actuated by the at least one control cam.

In addition to the coating operation, the CVD treatment may also comprise another surface treatment, such as for example surface activation in the vapor phase.

The opening and closing of the reactor can be automated in a simple way if the device for opening and closing the reactor is actuated by the reactor being moved past the control cam.

The reactor preferably comprises a first part and a second part, the parts surrounding a reactor chamber.

For this purpose, the first part may be connected to the conveyor and the second part may be connected to the opening and closing device. The two part design of the reactors allows a wide opening to the reactor chamber and therefore easy insertion and removal of the workpieces that are to be coated.

This can be achieved in particular through the control cam being arranged in such a way that the opening and closing device first of all, during opening, moves the second part away from the first part in a first movement and then moves it past the first part in a second movement that is substantially perpendicular to the first movement.

Particularly simple sealing of the two parts can be achieved by means of a planar sealing surface between the first and second parts.

Rotary and/or rectilinear devices can be used to convey the reactors and/or the workpieces to be coated therein.

Contact between the opening and closing device and the mechanical control cam can be produced, for example, by means of cam rolls which are secured to the device, so that the cam rolls roll along the control cam. In this way, frictional forces are avoided as the reactor moves past the control cam.

The reactor may have a window which transmits electromagnetic waves, in particular microwaves. As a result, the electromagnetic waves for generating the plasma can be generated outside the reactor, making it possible to dispense with a complex field applicator which is carried with the reactor.

The reactor may have an evacuator. As a result, the reactor chamber can be pumped out separately and it is not necessary to evacuate the entire device in order to provide the low pressure required for the plasma. Moreover, there may be a means for feeding in a process gas in order to fill the reactor chamber with the process gas.

The reactor may be equipped with a gas lance for feeding in a process gas. A gas lance can be used, for example, to rapidly feed a process gas to the interiors of hollow plastic bodies.

To convey the workpieces into the reactor and out of it, the CVD treatment device may be equipped with distribution wheels. These allow a continuous production process to be implemented in a simple way and without the need for a complex mechanism.

It is also within the scope of the invention to provide a process for the CVD treatment of workpieces in a reactor secured to a conveyor, which is distinguished by a particularly simple way of introducing and removing the workpieces. According to the invention, for this purpose the process comprises the steps of inserting the workpiece into the reactor, evacuating at least a region of the reactor chamber, introducing a process gas, generating a plasma and removing the workpiece, in which process the opening and/or closing the reactor is effected by means of a device secured to it by movement past a mechanical control cam.

The step of generating a plasma may comprise the step of radiating in electromagnetic waves. It is favorable to radiate in pulsed electromagnetic waves, with the result that a PICVD treatment of the workpieces is effected by the pulsed plasma in the vicinity of those surfaces of the workpiece which are to be coated. Moreover, the plasma can absorb a high radiation power as a result of microwaves being radiated in.

To achieve a large opening in the reactor chamber in order for the workpieces to be introduced and removed, the reactor may comprise at least two parts, which are moved past one another and onto one another during closing and/or opening of the reactor.

For a continuous coating sequence, it is advantageous for the workpieces to be introduced and removed by means of distribution wheels.

The process according to the invention can also be used for the CVD treatment of hollow bodies, such as, for example, bottles. To coat hollow bodies, the step of evacuating at least part of the reactor chamber may comprise the step of evacuating the volume surrounded by the hollow body. Particularly for internal coatings, for this purpose a process gas can be introduced into the volume surrounded by the hollow body. Finally, the process step of generating a plasma in the volume surrounded by the hollow body is responsible for the internal treatment of the hollow bodies.

### BRIEF DESCRIPTION OF THE DRAWINGS

The invention is explained in more detail below on the basis of preferred embodiments and with reference to the appended drawings, in which identical reference numerals denote identical or similar parts and in which:

FIG. 1 shows a partial cross-sectional view through an embodiment of a reactor,

FIG. 2 shows a plan view of the reactor, and

FIGS. 3A to 3D illustrate various phases of the introduction and removal of workpieces into and from the reactor.

### DETAILED DESCRIPTION OF THE INVENTION

FIG. 1 illustrates a partial cross-sectional view through an embodiment of a reactor for a device according to the invention for the CVD treatment of workpieces. This reactor is specifically designed to treat hollow bodies, in particular hollow plastic bodies, such as, for example, plastic bottles. The reactor, which is denoted overall by 3, comprises two parts 5 and 7 which surround a reactor chamber 9. The reactor chamber is sealed with respect to the environment by means of a seal 8 between the two parts 5 and 7. The sealing surface between the two parts 5 and 7 is in this case a planar surface.

A device 13 for opening and closing the reactor is secured to the part 7. This device 13 comprises an extension arm to which cam rolls 171, 172, 173 are secured, engaging around a control cam 15 which is arranged on the CVD treatment device. As a result, the cam rolls, by following the profile of the control cam 15, can make the second part 7 move away from the first part and past the first part in a direction perpendicular to the other movement.

A receiver 19 is used to fix the plastic bottle 11 which is to be coated and seals the interior of the bottle 11 off from the remaining volume of the reactor chamber 9.

In the first part of the reactor there is a passage 21 which is connected to a pump device and is used as a means for evacuating the reactor chamber. By way of example, in the case of a rotary device, the passage can be connected to a vacuum pump via a rotary vacuum leadthrough located in the center of the rotary device.

This embodiment of the CVD coating device can be used to coat hollow plastic bodies on both the outer side and on its inner walls. For this purpose, at the reactor there is also a gas lance 23, which can pass a suitable process gas into the interior of the bottle. The gas lance 23 is secured to a lifting device 25, so that the lance can be moved into the bottle when the bottle has been secured in the receiver 19 and can be moved back out of the interior of the bottle before the bottle is removed. For this purpose, the gas lance may be driven pneumatically or likewise by means of a control cam. The feed passage 29 is sealed off from the environment by means of a seal 27. For this purpose, the seal 27 may be designed as a radial seal or an axial seal. The gas lance is connected to a gas feed via a connection stub 29.

After the reactor chamber has been evacuated and the process gases have been admitted to the chamber, a plasma is generated by means of the action of microwaves in the chamber. The gas composition outside the bottle and inside the bottle or the hollow plastic body may differ. By way of example, the reactor chamber may be largely evacuated, so that only the residual gas which remains is located therein. By contrast, the process gas can be admitted to the interior of the bottle, which has been sealed off from the exterior space by the bottle receiver, via the gas lance. In this way, the action of microwaves leads to a plasma being formed only in the interior of the bottle, so that in this way only an internal coating is performed.

In particular, it is possible, if the bottles are sufficiently stable, only to evacuate the interior space, which is then filled again with a process gas via the gas lance. The high gas density which is present in the reactor chamber outside the bottle prevents the microwaves which are radiated in from generating a plasma in this region. As a result, a plasma is generated only in the interior of the bottle, which likewise leads to an internal coating or internal treatment of the bottle. The reactor shown in FIG. 1 is designed for this operating mode if the passage 21 is in communication only with the bottle opening, via the receiver.

The microwaves for generating the plasma may, for example, by introduced via a window 30 which is transparent to microwaves. This allows a field applicator to be arranged outside the reactor and therefore this applicator does not have to be carried with the chamber, which considerably simplifies the design of the CVD coating device.

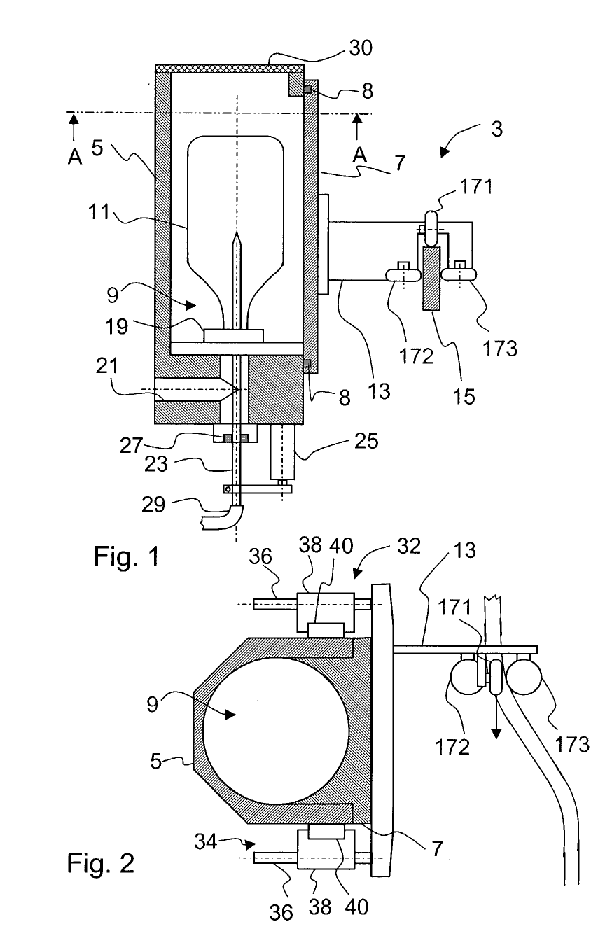

FIG. 2 shows a plan view of the reactor chamber on cross-sectional line A-A shown in FIG. 1. As can be seen from FIG. 2, the two parts 5 and 7 surround a reactor chamber 9 which is circular in cross section.

Moreover, the two parts are moveably connected to one another by means of two guides, which are denoted overall by 34 and 36. The guides 34 and 36 each comprise pins 36 that are fixedly connected to the part 7 and are guided in a block 38, so that the part 7 can move along the longitudinal axis of the pins relative to part 5. Moreover, the blocks 38 are guided in guide rails 40, so that part 7 can also be displaced relative to part 5 in a movement of part 7 which is perpendicular with respect to the longitudinal axes of the pins 36. Therefore, the guidance allows the chambers to be moved away from one another and past one another. The movement is in this case imparted by the mechanical control cam 15 via the opening and closing device.

The section of the control cam which is illustrated in FIG. 2 is shaped in such a way that, in the event of the conveyor and therefore the reactor connected to it moving in the direction indicated by the arrow, the part 7 is moved away from the part 5, so that the reactor chamber is opened.

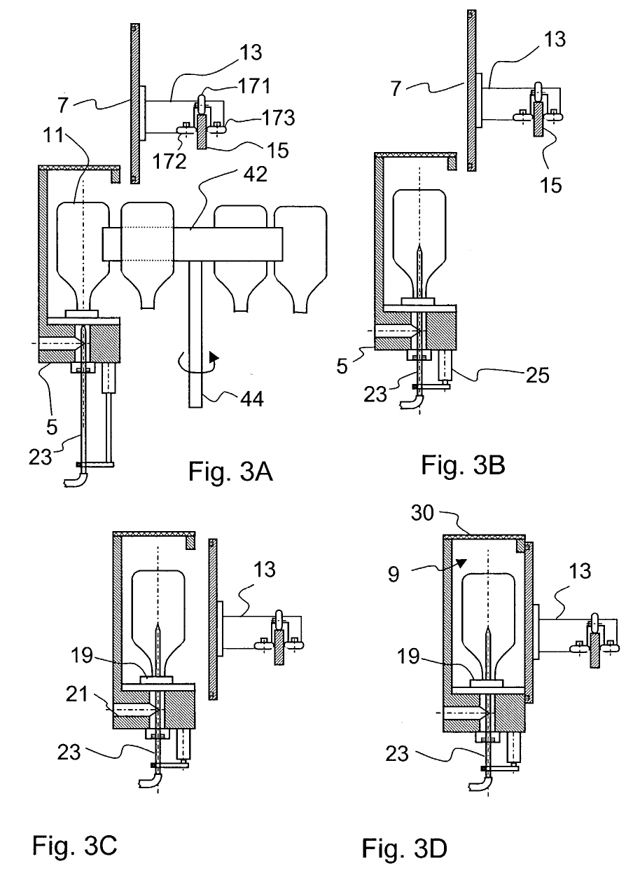

The operation of introducing and removing workpieces is explained in more detail with reference to FIGS. 3A to 3D. In this example, the reactor is likewise used to coat hollow plastic bodies, in particular plastic bottles. FIG. 3A shows a first phase of introduction, in which the reactor chamber has been opened and a bottle 11 is being conveyed into the chamber by means of a distribution wheel 42 which is rotated about a spindle 44. The bottle 11 is then inserted into the receiver 19. To enable the bottle to be inserted into the receiver, the gas lance 23 has been pulled out of the reactor chamber during this section of the process.

After the bottle has been inserted into the bottle receiver 19, the gas lance, as shown in FIG. 3B, is moved into the interior of the bottle 11 that is to be coated.

After the bottle 11 has been inserted, the part 7 of the reactor is first of all moved along part 3 of the reactor by means of the control cam 15 and pushed to in front of the opening of the reactor chamber, as illustrated in FIG. 3C.

Finally, as shown in FIG. 3D, the part 7 of the reactor is moved onto the part 5 of the reactor by means of a second movement of the control cam 15, so that the opening of the reactor chamber 9 is closed. The chamber and/or the interior of the bottle are then evacuated by means of a pump device connected to the passage 21. Then, the process gas can be admitted via the gas lance. Microwaves can be radiated into the chamber through the window 30, so that the process gas forms a plasma and the reaction products coat the adjacent walls. In this example, the process gas is only passed into the interior of the bottle, leading to internal coating of the bottles, for example as a diffusion barrier.

Following the coating, the bottle is removed again, for which purpose the steps described above are carried out in the reverse order.

We claim:

1. A device for the CVD treatment of workpieces, comprising a conveyor and at least one reactor secured to the conveyor, wherein the device has at least one mechanical control cam and the reactor has an opening and closing device which is actuated by the at least one control cam.

2. The device as claimed in claim 1, wherein the device for opening and closing the reactor is actuated by the reactor being moved past the control cam.

3. The device as claimed in claim 1, wherein the reactor comprises a first part and a second part, the parts surrounding a reactor chamber.

4. The device as claimed in claim 3, in which the first part is connected to the conveyor and the second part is connected to the opening and closing device.

5. The device as claimed in claim 3, wherein the control cam is arranged in such a way that the opening and closing device firstly, during opening, moves the second part away from the first part in a first movement and then moves the second part past the first part in a second movement that is substantially perpendicular to the first movement.

6. The device as claimed in claim 3, which comprises a planar sealing surface between the first and second parts.

7. The device as claimed in claim 1, in which the conveyor comprises a rotary device.

8. The device as claimed in claim 1, in which the conveyor comprises a rectilinear device.

9. The device as claimed in claim 1, wherein the opening and closing device comprises cam rolls.

10. The device as claimed in claim 1, wherein the reactor comprises a window which is transparent to electromagnetic waves, in particular microwaves.

11. The device as claimed in claim 1, wherein the reactor comprises an evacuator.

12. The device as claimed in claim 1, which comprises a device for feeding in a process gas.

13. The device as claimed in claim 12, in which the device for feeding in a process gas comprises a gas lance.

14. The device as claimed in claim 1, which comprises at least one distribution wheel.

15. A process for a CVD treatment of workpieces in a reactor which is secured to a conveyor, comprising the steps of:
inserting the workpiece into the reactor,
evacuated at least a region of the reactor chamber,
introducing a process gas,
generating a plasma,
removing the workpiece,
which process also comprises the step of
opening and/or closing the reactor by a device secured to the reactor by movement past a mechanical control cam.

16. The process as claimed in claim 15, wherein the step of generating a plasma comprises the step of radiating in electromagnetic waves.

17. The process as claimed in claim 16, wherein the step of radiating in electromagnetic waves comprises the step of radiating-in pulsed electromagnetic waves.

18. The process as claimed in claim 16, wherein the step of radiating in electromagnetic waves comprises the step of radiating in microwaves.

19. The process as claimed in claim 15, in which the reactor comprises at least two parts, wherein the step of closing and/or opening the reactor comprises the step of moving the at least two parts past one another and onto one another.

20. The process as claimed in claim 15, in which the step of inserting the workpiece comprises the step of introducing the workpiece by way of a distribution wheel.

21. The process as claimed in claim 15, in which the step of removing the workpiece comprises the step of removing the workpiece by way of a distribution wheel.

22. The process as claimed in claim 15, in which the workpiece comprises a hollow body.

23. The process as claimed in claim 22, wherein the workpiece comprises a bottle.

24. The process as claimed in claim 22, in which the step of evacuating at least part of the reactor chamber comprises the step of evacuating a volume surrounded by the hollow body.

25. The process as claimed in claim 22, in which the step of introducing a process gas comprises the step of introducing a process gas into a volume surrounded by the hollow body.

26. The process as claimed in claim 22, in which the step of generating a plasma comprises the step of generating a plasma in a volume surrounded by the hollow body.
